(19) United States
(12) Patent Application Publication
(10) Pub. No.: US 2026/0327847 A1
(43) Pub. Date: Oct. 22, 2026

(54) METHODS FOR EPITAXIAL GROWTH OF GOLD NANOSTRUCTURES ON TRANSITION METAL DICHALCOGENIDES

(71) Applicant: CITY UNIVERSITY OF HONG KONG, KOWLOON (HK)

(72) Inventors: Thuc Hue LY, Kowloon (HK); Ka Ho LEUNG, Kowloon (HK)

(21) Appl. No.: 19/351,254

(22) Filed: Oct. 6, 2025

Related U.S. Application Data
(60) Provisional application No. 63/792,905, filed on Apr. 22, 2025.

(51) Int. Cl. C30B 23/02; C30B 25/18; C30B 29/02; C30B 29/46; C30B 29/68; C30B 33/02

(52) U.S. Cl. CPC C30B 23/025; C30B 25/18; C30B 29/02; C30B 29/46; C30B 29/68; C30B 33/02

(57) ABSTRACT

Provided herein is a method for producing a gold nanostructure on a sacrificed single-layer transition metal dichalcogenide (TMD). The method includes: (a) placing precursors of a single-layer TMD and a SiO₂/Si substrate in a chamber having a heating zone, wherein the precursors of the single-layer TMD are disposed upstream to the heating zone while the SiO₂/Si substrate is disposed in the heating zone; (b) raising the temperature in the heating zone to 800-840° C. within 30 minutes in the presence of an inert gas and maintaining the temperature for 15 minutes to allow aligned growth of the single-layer TMD on the SiO₂/Si substrate; (c) sputter-coating the product of step (b) with a film of gold; and (d) annealing the product of step (c) at 600° C. for 20 minutes to degrade the single-layer TMD thereby producing a AuNS on a sacrificed single-layer TMD. According to embodiments of the present disclosure, the AuNS on the sacrificed single-layer TMD exhibits an enhanced photoluminescence signal as compared to that of a gold nanostructure grown directly on the SiO₂/Si substrate.

### CROSS-REFERENCE TO RELATED APPLICATIONS

This application claims priority and the benefit of U.S. Provisional Patent Application No. 63/792,905, filed Apr. 22, 2025, the entirety of which is incorporated herein by reference.

### BACKGROUND OF THE INVENTION

### 1. Field of the Invention

The present invention relates to the production of gold nanostructures on transition metal dichalcogenide (TMD) film.

### 2. Description of Related Art

Gold, among the most renowned metals on Earth, is esteemed for its distinctive color and exceptional stability in everyday use. Furthermore, scientific exploration of gold and gold nanostructures is highly regarded for their exceptional performance across a multitude of applications, including medicine, catalyst, environmental and plasmonic.—The effectiveness of gold nanostructures in these domains is significantly influenced by several factors, such as shape, size and crystal structures. To meet the demand for precise control over gold synthesis, various methodologies have been documented, predominantly revolving around wet chemical techniques such as Turkevich, Brust-Schiffrin, and seed-mediated growth.

Apart from wet chemical methods, preparation of gold nanostructures and more importantly, their subsequent patterning process can also be achieved by physical processes. By employing techniques like e-beam or thermal deposition of gold nanofilm followed by thermal treatment, it can lead to the formation of distinct gold nanostructures from the initial film. The effectiveness of this transformation is significantly influenced by several factors, including the annealing temperature, which can dictate the size and shape of the resulting nanostructures, as well as the thickness of the gold nanofilm, which determines the initial amount of material available for structuring. By carefully controlling these parameters, researchers can achieve a wide range of gold nanostructures which can be tailored for specific applications in areas such as electronics and photonics.

In addition to the previously mentioned applications, gold plays a crucial role in the synthesis of various nanomaterials, notably in the fabrication of two-dimensional (2D) transition metal dichalcogenides (TMDCs). Gold nanostructures frequently act as substrates or seeds that guide and control the synthesis of these 2D materials. For instance, in the process of creating thin films, gold nanostructures can induce orientation-directed growth, ensuring that the resulting layers align in a specific manner. Similarly, particle-like structures of gold can direct the growth of nanotubes, allowing for tailored properties and functionalities in the final products. Furthermore, precise patterning technique is employed to control the seeding process, leading to enhanced uniformity and scalability in the synthesis of TMDCs.

The success of these methods is largely attributed to the advantageous properties of gold, particularly its shared crystal structure with certain TMDCs and the robust interaction between sulfur and gold. This interaction facilitates the epitaxial growth of sulfur-based TMDCs, such as molybdenum disulfide (MoS₂) and tungsten disulfide (WS₂). The compatibility of gold nanostructures with these materials not only improves the quality of the TMDCs produced but also opens up new avenues for exploring the reciprocal influence, where gold nanostructures are tailored based on the properties of the TMDCs being synthesized.

Inventors of the present disclosure unexpectedly found that using 2D monolayer MoS₂ as the sacrificial epitaxial substrate can guide and accelerate the crystallization of sputtered gold nanofilm, allowing the patterning of more regular and larger sized gold nanostructures compared to non-crystalline SiO₂/Si surface. The thus produced MoS₂-guided gold nanostructures exhibit a significant enhancement in photoluminescence (PL) signal of AuNS/MoS₂ heterostructure, demonstrating the potential of plasmonic applications.

### SUMMARY

Embodiments of the present disclosure relate to methods for the epitaxial growth of a gold nanostructure (AuNS) on single-layer transition metal dichalcogenide (TMD), methoand methods for forming stacked TMD/AuNS heterostructures.

Accordingly, the first aspect of the present disclosure aims at providing a method for producing an AuNS on a sacrificed single-layer transition metal dichalcogenide (TMD). The method comprises:
(a) placing precursors of a first single-layer TMD and a first SiO₂/Si substrate in a chamber having a heating zone, wherein the precursors of the first single-layer TMD are disposed upstream to the heating zone while the first SiO₂/Si substrate is disposed in the heating zone;
(b) raising the temperature in the heating zone to 800-840° C. within 30 minutes in the presence of an inert gas and maintaining the temperature for 15 minutes to allow aligned growth of the first single-layer TMD on the first SiO₂/Si substrate;
(c) sputter-coating the product of step (b) with a film of gold (Au); and
(d) annealing the product of step (c) at 600° C. for 20 minutes to degrade the first single-layer TMD thereby producing the AuNs on the sacrificed single-layer TMD;
wherein,
the AuNS on the sacrificed single-layer TMD exhibits an enhanced photoluminescence signal as compared to that of a gold nanostructure grown directly on the first SiO₂/Si substrate.

According to embodiments of the present disclosure, in step (a), the precursors of the first single-layer TMD are sulfur or selenium powders and MoO₃, and the first single-layer TMD is single-layer MoS₂ or MoSe₂; and in step (b), the temperature in the heating zone is raised to 840° C.

According to alternative embodiments of the present disclosure, in step (a), the precursors of the first single-layer TMD are sulfur or selenium powders and WO₃, and the first single-layer TMD is single-layer WS₂ or WSe₂; in step (b), the temperature in the heating zone is raised to 820° C.

Examples of the inner gas suitable for use in the present disclosure include, but are not limited to, argon, helium, nitrogen, etc. According to preferred embodiments of the present disclosure, the inner gas is argon.

According to embodiments of the present disclosure, the AuNS on the single-layer TMD exhibits two times enhancement on the photoluminescence signal as compared to that of the AuNS grown directly on the SiO₂/Si substrate.

According to optional embodiments of the present disclosure, the method further comprises:
(e) stacking a second single-layer TMD onto the present AuNS on the sacrificed single-layer TMD by a dry transfer method thereby forming a TMD/AuNS stacked heterostructure;
wherein, the TMD/AuNS stacked heterostructure exhibits four times enhancement on the photoluminescence signal as compared to that of the AuNS grown directly on the first SiO₂/Si substrate.

According to embodiments of the present disclosure, the second single-layer TMD is produced by,
(i) placing precursors of a second single-layer TMD and a second SiO₂/Si substrate in the chamber having the heating zone, wherein the precursors of the second single-layer TMD are disposed upstream to the heating zone while the second SiO₂/Si substrate is disposed in the heating zone; and
(ii) raising the temperature in the heating zone to 800-840° C. within 30 minutes in the presence of an inert gas and maintaining the temperature for 15 minutes to allow aligned growth of the second single-layer TMD on the second SiO₂/Si substrate.

According to embodiments of the present disclosure, the dry transfer method is performed by steps of:
(1) spin-coating the second single-layer TMD of step (ii) with a transfer film;
(2) removing the second SiO₂/Si substrate from the product of step (1);
(3) placing the product of step (2) on top of the AuNS on the sacrificed single-layer TMD of step (d) with the second single-layer TMD contacting the present AuNS on the sacrificed single-layer TMD;
(4) heating the product of step (3) at 120° C. for 2 minutes; and
(5) peeling off the transfer film from the heated product of step (4) thereby producing the TMD/AuNS stacked heterostructure.

Examples of the materials suitable for use as the transfer film in the present method include, but are not limited to, polydimethylsiloxane (PDMS), poly(methyl methacrylate) (PMMA), and etc. In some embodiments, the transfer film is made of PDMS. In other embodiments, the transfer film is made of PMMA.

According to embodiments of the present disclosure, the first or second single-layer TMD may be selected from the group consisting of single-layer MoS₂, single-layer WS₂, single-layer MoSe₂, and single-layer WSe₂.

Other and further embodiments of the present disclosure are described in more detail below.

### BRIEF DESCRIPTION OF THE DRAWINGS

The disclosure will become more fully understood from the detailed description and the drawings given below for illustration only, and thus does not limit the disclosure, wherein:

FIG. 1 is a schematic diagram depicting the synthesis of TMD flakes and preparation of gold nanostructures in accordance with some preferred embodiments of the present disclosure;

FIG. 2 is a flowchart of the method 100 depicted in FIG. 1;

FIG. 3 is a schematic diagram depicting the synthesis of AuNS stacked heterostructure in accordance with one preferred embodiment of the present disclosure;

FIGS. 4(a)-4(d) are SEM image of FIG. 4(a) MoS₂/SiO₂/Si, FIG. 4(b) Au/MoS₂/SiO₂/Si,

FIG. 4(c) AuNS/SiO₂/Si using in-house CVD growth MoS₂, and FIG. 4(d) annealed AuNS/SiO₂/Si prepared using mechanically exfoliated MoS₂ in accordance with preferred embodiments of the present disclosure, in which scale bars=1 μm;

FIGS. 5(a)-5(d) are FIG. 5(a)-FIG. 5(b) HAADF-STEM images of sacrificed-MoS₂ AuNS with denoted surfaces (scale bars, 50 nm), and (FIG. 5c, FIG. 5d) corresponding selected area electron diffraction (SAED) images (scale bars, 10 nm⁻¹) in accordance with one preferred embodiment of the present disclosure and

FIGS. 6(a)-6(b) are FIG. 6(a) optical image and FIG. 6(b) single point PL spectrum FIG. 6(b) for pristine MoS₂ and AuNS/MoS₂ stacked structure in accordance with one embodiment of the present disclosure, scale bar, 10 μm.

### DETAILED DESCRIPTION

Detailed descriptions and technical contents of the present disclosure are illustrated below in conjunction with the accompanying drawings. However, it is to be understood that the descriptions and the accompanying drawings disclosed herein are merely illustrative and exemplary and not intended to limit the scope of the present disclosure.

### 1. Epitaxial Growth of AuNS on Sacrificed Single-Layer TMD

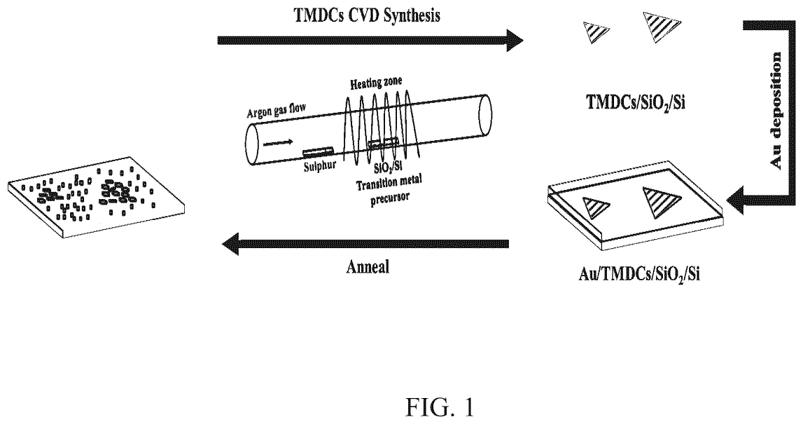

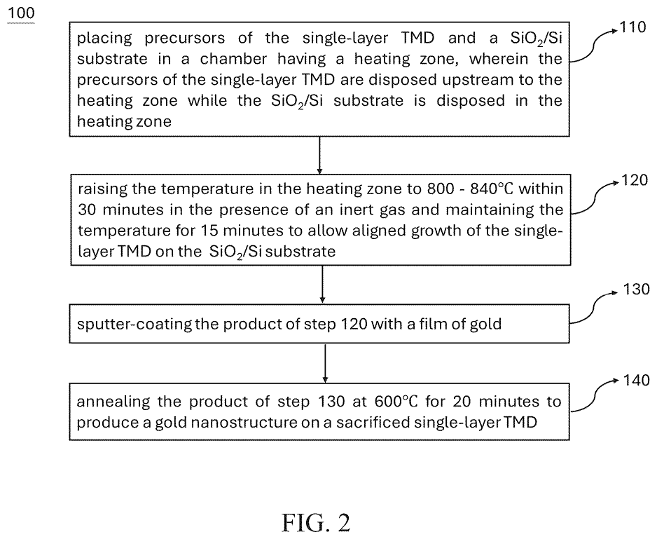

One aspect of the present disclosure aims at providing a method of producing AuNS on a sacrificed single-layer TMD. References are made to FIGS. 1 and 2, in which FIG. 1 is a schematic diagram depicting the synthesis of TMD flakes and preparation of AuNS, while FIG. 2 is a flowchart for performing the process depicted in FIG. 1. As shown in FIG. 1, the present method is performed in a one-zone chamber, such as a chemical vapor deposition (CVD) chamber having a heating zone. As shown in the flowchart, the present method 100 commences by placing precursors of 2D TMD (e.g., precursors of MoS₂) in a zone upstream to the heating zone, while the first SiO₂/Si substrate is placed in the heating zone (S110). Depending on the TMD intended to form, suitable precursors are selected and placed in the single-zone CVD chamber. In some embodiments, elemental sulfur(S) and Molybdenum trioxide (MoO₃) for the synthesis of MoS₂ are placed in the single-zone CVD chamber. In other embodiments, elemental sulfur(S) and tungsten trioxide (WO₃) for the synthesis of WS₂ are placed in the single-zone CVD chamber. In some embodiments, elemental selenium (Se) and MoO₃ for the synthesis of MoSe₂ are placed in the single-zone CVD chamber. In other embodiments, elemental selenium (Se) and WO₃ for the synthesis of WSe₂ are placed in the single-zone CVD chamber.

According to embodiments of the present disclosure, the temperature in the single-zone CVD chamber is raised to about 800-840° C. within 30 minutes in the presence of an inert gas and maintaining the temperature for another 15 minutes to allow aligned growth of the single-layer TMD on the SiO₂/Si substrate (S120). Examples of inert gas suitable for use in S120 include, but are not limited to, argon, helium, nitrogen, etc. Preferably, S120 is conducted in the presence of 200 sccm Ar gas. In the case when single-zone CVD chamber contains precursors of MoS₂ (i.e., elemental sulfur(S) and MoO₃), the temperature of the single-zone CVD chamber is raised to 840° C. in 30 minutes and kept at 840° C. for additional 15 minutes under 200 sccm Ar to allow aligned growth of MoS₂ on the SiO₂/Si substrate. In the case when single-zone CVD chamber contains precursors of WS₂ (i.e., elemental sulfur(S) and WO₃), the temperature of the single-zone CVD chamber is raised to 820° C. in 30 minutes and kept at 820° C. for additional 15 minutes under 200 sccm Ar to allow aligned growth of WS₂ on the SiO₂/Si substrate.

A layer of gold is then sputter deposited onto the TMD film of S120 thereby forming the structure of Au/TMD/SiO₂/Si (S130).

Then, the temperature in the single-zone CVD chamber is then raised to an annealing temperature to degrade the first single-layer TMD layer. Specifically, the temperature in the single-zone CVD chamber is raised to 600° C. and kept at the annealing temperature for 20 minutes to degrade the first single-layer TMD thereby producing an AuNS on a sacrificed single-layer TMD (S140). According to embodiments of the present disclosure, the thus produced AuNS on the sacrificed single-layer TMD exhibits an enhanced photoluminescence signal as compared to that of a gold nanostructure grown directly on the first SiO₂/Si substrate. Preferably, the AuNS on the sacrificed single-layer TMD exhibits two times enhanced photoluminescence signal as compared to that of a gold nanostructure grown directly on the first SiO₂/Si substrate.

### 2. TMD/AuNS Stacked Heterostructure

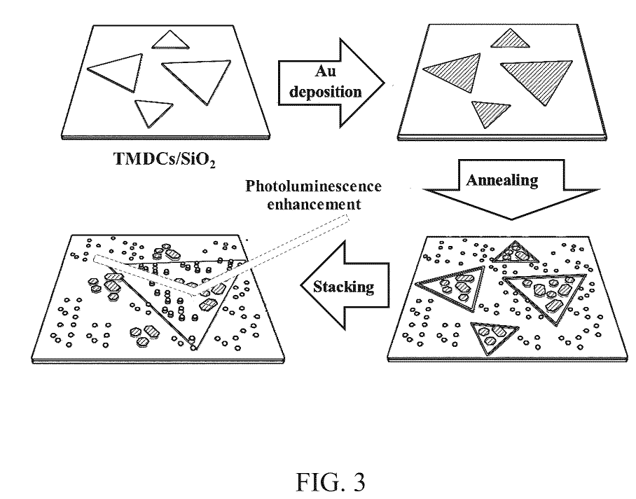

Alternatively or in addition, the present method 100 described above further includes steps for forming a TMD/AuNS stacked heterostructure, which comprises an additional single-layer TMD stacked on the AuNS on the sacrificed single-layer TMD of S140. Reference is made to FIG. 3, which is a schematic diagram depicting the process for forming TMD/AuNS stacked heterostructure, in which a newly synthesized single-layer TMD is transferred and stacked onto the product of S140 (i.e., the AuNS on a sacrificed single-layer TMD). To this purpose, a second single-layer TMD is synthesized on another SiO₂/Si substrate or a growth substrate by similar steps described above for synthesizing the first single-layer TMD on a target substrate (i.e., the first SiO₂/Si substrate). Similarly, depending on the second single-layer TMD intended to form, suitable precursors are selected and placed in the single-zone CVD chamber. In some embodiments, elemental sulfur(S) and MoO₃ for the synthesis of MoS₂ are placed in the single-zone CVD chamber. In other embodiments, elemental sulfur(S) and WO₃ for the synthesis of WS₂ are placed in the single-zone CVD chamber. In some embodiments, elemental selenium (Se) and MoO₃ for the synthesis of MoSe₂ are placed in the single-zone CVD chamber. In other embodiments, elemental selenium (Se) and WO₃ for the synthesis of WSe₂ are placed in the single-zone CVD chamber.

Then, the temperature in the single-zone CVD chamber is raised to about 800-840° C. within 30 minutes in the presence of an inert gas and maintaining the temperature for another 15 minutes to allow aligned growth of the second single-layer TMD on the second SiO₂/Si substrate. Examples of inert gas suitable for use in the present step include, but are not limited to, argon, helium, nitrogen, etc. Preferably, the synthesis of the second single-layer TMD is conducted in the presence of 200 sccm Ar gas. In the case when single-zone CVD chamber contains precursors of MoS₂ (i.e., elemental sulfur(S) and MoO₃), the temperature of the single-zone CVD chamber is raised to 840° C. in 30 minutes and kept at 840° C. for additional 15 minutes under 200 sccm Ar to allow aligned growth of MoS₂ on the second SiO₂/Si substrate. In the case when single-zone CVD chamber contains precursors of WS₂ (i.e., elemental sulfur(S) and WO₃), the temperature of the single-zone CVD chamber is raised to 820° C. in 30 minutes and kept at 820° C. for additional 15 minutes under 200 sccm Ar to allow aligned growth of WS₂ on the second SiO₂/Si substrate.

The thus synthesized second single-layer TMD is then transferred onto the AuNS/sacrificed single-layer TMD of step S140 by any known method, such as by use of a dry transfer method.

According to embodiments of the present disclosure, the dry transfer method is performed by:
(1) spin-coating the second single-layer TMD disposed on the second SiO₂/Si substrate with a transfer film;
(2) removing the second SiO₂/Si substrate from the product of step (1);
(3) placing the product of step (2) on top of the AuNS on the sacrificed single-layer TMD of S140 with the second single-layer TMD contacting the present AuNS on the sacrificed single-layer TMD;
(4) heating the product of step (3) at 120° C. for 2 minutes; and
(5) peeling off the transfer film from the heated product of step (4) thereby producing the TMD/AuNS stacked heterostructure.

Exemplary materials suitable for use as the transfer film in the present method include, but are not limited to, polydimethylsiloxane (PDMS), poly(methyl methacrylate) (PMMA), and etc. In some embodiments, the transfer film is made of PDMS. In other embodiments, the transfer film is made of PMMA.

According to embodiments of the present disclosure, the TMD/AuNS stacked heterostructure exhibits four times enhanced photoluminescence signal as compared to that of a gold nanostructure grown directly on the first SiO₂/Si substrate.

The present invention will now be described more specifically with reference to the following embodiments, which are provided for the purpose of demonstration rather than limitation. While they are typically of those that might be used, other procedures, methodologies, or techniques known to those skilled in the art may alternatively be used.

### Examples

### Material and Methods

Preparation of MoS₂ and WS₂

The MoS₂ flake were synthesized using a single heating zone furnace under atmospheric pressure on 300 nm SiO₂/Si substrate. Sulfur powder (50 mg) and MoO₃ (5 mg) served as the sulfur and molybdenum source respectively. The MoS₂ was synthesized at 820° C. with the ramping rate of 30° C./min under 200 sccm Ar for 15 mins, the furnace then naturally cooled down to room temperature.

The WS₂ was synthesized in accordance with procedures similar to that for MoS₂, except MoO₃ was replaced by WO₃ (5 mg) and the temperature was set at 840° C.

### Preparation of Gold Nanostructures on MoS₂

The SiO₂/Si substrate with synthesized MoS₂ flakes were sputtered by nanometers of gold film using an ion sputter (BAL-TEC, SCD 050), with a working current of 60 mA and sputter time of 10s. The sputtered substrate then annealed under 600° C. with the ramping rate of 30° C. min⁻¹ for 10 mins and cooled down to room temperature naturally under Argon environment.

### Transfer of Gold Nanostructures and MoS₂

The gold nanostructures/MoS₂ was transferred by traditional Poly(methyl methacrylate) (PMMA)-assisted wet transfer. PMMA (10 μm, A4) was spin coated on the as-grown MoS₂/SiO₂/Si by 3,000 rpm for 60s. The substrate then placed floating on the surface of NaOH solution to allow the PMMA film to detach from SiO₂/Si substrate. The detached PMMA film was placed in deionized water to wash off remaining ions and finally transferred to TEM grid, and the PMMA was removed by rinsing with acetone, isopropanol and ethanol, respectively.

### Fabrication of MoS₂/Gold Nanostructure Stacked Heterostructure

The stacked heterostructure was prepared using a transfer platform equipped with an optical microscope. SiO₂/Si substrate with annealed gold nanostructure on SiO₂/Si substrate was fixed on the transfer platform while the polydimethylsiloxane (PDMS)/PMMA film with MoS₂ was fixed on the upper half of the transfer platform. With the aid of optical microscope, the position of targeted MoS₂ and gold nanostructures was located and adjusted to designated positions that were controlled separately, the height difference between SiO₂/Si and PDMS then reduced subsequently with the trace of the position of MoS₂ and gold nanostructures until PDMS film firmly attached to the SiO₂/Si substrate. The platform was heated to 120° C. for 2 mins to weaken the adhesive strength of PDMS, and the PDMS layer was slowly removed vertically leaving PMMA film on top of the SiO₂/Si substrate, as the final structure of PMMA/MoS₂/gold nanostructures/SiO₂/Si was prepared.

### Material Characterizations

The MoS₂ flakes and gold nanostructures were observed through an optical microscope (ZEISS Imager.A2M) under bright field and dark field. Detailed morphology of gold nanostructures was acquired by scanning electron microscope (ThermoFisher, Quattro S), with the spot size of 3.0 and electron beam energy of 10 kV. The topology of gold nanostructures was characterized by atomic force microscopy (Hitachi 5300E) under dynamic force mode with the SI-DF3 silicon tip. The crystal structure of gold nanostructures was acquired by high-resolution STEM using a JEM-ARM200F TEM with a CEOS spherical (Cs) aberration (probe) corrector. The aberration-corrected STEM image was taken under 300 kV of the accelerating voltage of electron beam. The structural and optical properties were examined by Raman system (Renishaw, inVia confocal), equipped with an excitation laser of 514 nm and grating of 1800 g/nm under normal operating mode, the measuring parameters were set with exposure time of 5s and laser power of 5% respectively unless specified. The photoluminescence spectra of MoS₂ and stacked structure was measured by the same Raman system with an excitation laser of 514 nm, exposure time for each spectrum is 10s and laser power of 1% respectively unless specified.

### Example 1: Preparation and Characterization of the Present Gold Nanostructures

### 1.1 Epitaxial Growth of AuNS on Sacrificed Single-Layer TMD

The AuNS were prepared by epitaxial growth on TMDs in accordance with procedures described in the “Materials and methods” section, specifically, by the process depicted in FIG. 1. Briefly, 2D monolayer MoS₂ was first synthesized via chemical vapor deposition on a SiO₂/Si substrate, followed by gold sputtering and annealing, which resulted in the formation of various gold nanostructures on the substrate. These structures were categorized based on their size and morphology into two types: those formed on the MoS₂ layer (sacrificed-MoS₂ AuNS) and those formed on the SiO₂/Si substrate surface.

The gold nanofilm was deposited via sputtering method. Limited by the performance of sputtering machine and to minimize error, the deposition time was limited to 10 seconds with the measured thickness of about 5 nm according to the AFM topography (data not shown). Apart from the original nanofilm thickness, series of annealing with varying temperature and time were conducted to investigate its effects on the formation of gold nanostructures. Starting at 200° C., the gold film remained intact in both regions, with no significant changes observed. As the temperature increased, the gold in direct contact with SiO₂/Si began to melt, forming a hemispheric shape, while the gold in contact with MoS₂ retained its sputtered film structure. At 400° C., the gold on MoS₂ developed a unique network-like morphology, exposing parts of the SiO₂/Si substrate in between, while the central area remained intact. This trend indicated that the formation of gold nanostructures on the MoS₂ surface required higher energy, originating from the edges of MoS₂ and progressing toward the center. Consequently, 600° C. was selected as the minimum temperature necessary to form rigid gold nanostructures using this method.

At this temperature, a series of time variations were studied to examine the effect of annealing duration. After annealing at 600° C. for 1 or 5 minutes, the gold nanostructures formed on the MoS₂ surface were less rigid and had more curved edges compared to those subjected to longer annealing times. This suggested that not only temperature, but also time, significantly affected the morphology of gold nanostructures. Based on these findings, the synthesis parameters for gold nanostructures in the subsequent part of this work were set at an annealing temperature of 600° C. for 20 minutes.

Notably, the melting point of gold nanofilm was significantly reduced compared to the melting point of bulk gold which exceeded 1,000° C. This phenomenon is known as the size-dependent melting point depression. When the size of material is reduced to nanoscale, its surface-to-volume ratio increases substantially. The rapid change leads to surface effects, including variations in surface energy and surface tension, In addition to the lattice structure of nanosolids, these factors result in change of melting behavior of material.

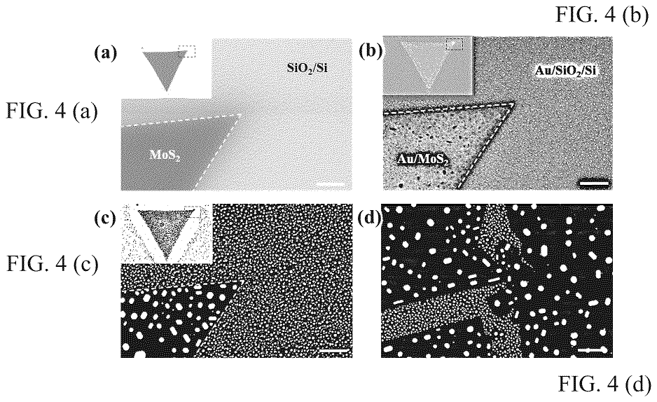

SEM images in FIG. 4(a)-FIG. 4(d) show the in-situ evolution of single MoS₂ flake throughout the process as depicted in FIG. 1, the clear contrast difference in FIG. 4(a) shows the synthesized MoS₂ on SiO₂/Si, which the darker part was the MoS₂ flake with lower conductivity compared to SiO₂/Si. After sputtering with gold, the entire substrate surface was covered and thus no significant contrast between MoS₂ and SiO₂/Si was observed (FIG. 4(b)). After the annealing process, the gold film turned into nanostructures, with the MoS₂ region labelled in FIG. 4(c) showed the distribution difference between MoS₂ and SiO₂/Si, in which this difference was observed on exfoliated MoS₂ transferred to SiO₂/Si substrate (FIG. 4(d)). Comparing the gold nanostructures formed on MoS₂ and SiO₂/Si, it was evident that the sacrificed-MoS₂ AuNS exhibited more regular shapes and appeared larger in size, primarily appeared rod-like or hexagonal form. In contrast, the gold nanostructures formed on SiO₂/Si were generally smaller and spherical in shape. We also measured the height of the gold nanostructures using AFM topography and compared these measurements to the sputtering height (data not shown). The synthesized MoS₂ monolayer was examined by Raman spectroscopy (data not shown), apart from characteristic E¹_{2g} and A_{1g} peak of MoS₂, the inter peak distance in Raman spectrum was used to determine the number of layers of MoS₂, in which the distance was 18.3 cm⁻¹, confirming the single layered nature of the synthesized MoS₂.

### 1.2 Characterization of the Gold Nanostructures of Example 1.1

The gold nanostructures were examined by scanning electron microscope and atomic force microscope for more detailed observation. It was found that the height of sacrificed-MoS₂ AuNS increased from 5 nm to 40-55 nm (data not shown), like the structures formed on SiO₂/Si surface. This indicated that the sputtered gold melted and aggerated to form various gold nanostructures during annealing. Previous reports have shown that the deposited thickness of gold is related to the final shape of the gold nanostructures after such heat treatment, with approximately 8-10 nm of original gold nanofilm required to achieve a similar morphology compared to this study. In this example, we demonstrated that the sacrificial 2D TMDCs enabled preparation of target gold nanostructures with reduced initial thickness and the distribution of these nanostructures was completely related to the MoS₂ presence on same substrate.

To elucidate the correlation between the formation of gold nanostructures and TMDCs, additional TMDCs were employed for comparative analysis. Specifically, 2D WS₂ and ReS₂ were utilized for gold nanostructure synthesis following this proposed scheme, and the resultant structures were examined under SEM. It is evident that similar results were achieved only with WS₂, but not with ReS₂. Although MoS₂, WS₂, and ReS₂ belong to the same category of sulfide-based TMDCs, the differences in results could be attributed to their distinct crystal structures. Both MoS₂ and WS₂, as 2H-phase crystals, exhibited similar structures with minor variations in lattice constants due to the slight atomic size difference between Mo and W. By contrast, ReS₂, in its 1T′ phase, possesses a distinctly different atomic arrangement. The observed divergence in outcomes may be explained by the 2H-phase materials acting as nucleation sites, which expedited the crystallization of gold nanostructures due to the inherent characteristics of the 2H-phase lattice. Previous researches have explored the epitaxial relationship between face-centered cubic (fcc) Au and 2H-MoS₂, more specifically, the plane of Au and plane of MoS₂. As reproted by Cui et al., the lattice mismatch between Au planes and MoS₂ planes yielded a Moire pattern with spacing |Δgₐ|⁻¹ equal to 1.63 nm and observed under TEM (Y. Cui et al., Science 2024, 383, 212). The epitaxial relationship between MoS₂ and Au explained the MoS₂ layer underneath gold nanofilm with small lattice mismatch served as a template substrate which guided the arrangement of gold atoms and thus promoted the formation of hexagonal AuNS.

Further, this preparation method was not limited to TMDCs grown by CVD; MoS₂ produced via mechanical exfoliation also demonstrates similar results, as shown in FIG. 4(d), thus eliminating the substrate effects associated with CVD growth.

In addition to the possible cause of wetting behavior difference between MoS₂ and SiO₂/Si, a set of gold nanofilm thickness experiment was conducted. Various thickness of gold nanofilm were prepared through sputtering and annealed under 600° C. as described in the “Materials and methods” section. Unlike significant difference in terms of the morphology of AuNS between MoS₂ and SiO₂/Si, similar hexagonal AuNS could also be found on SiO₂/Si substrate when gold nanofilm thickness increased (data not shown). Thus, we further increased the thickness of sputtered gold nanofilm to ~27 nm, as turns out not only the AuNS on SiO₂/Si, but also some of the AuNS in previous MoS₂ region were irregular (data not shown), nevertheless, hexagonal AuNS could be in both regions. The result demonstrated control of AuNS morphology could be achieved by controlling gold nanofilm thickness on SiO₂/Si and as reported on other substrates, proved the formation of rigid AuNS did not originate from the wetting behavior difference between MoS₂ and SiO₂/Si.

The AuNS prepared with different initial gold nanofilm thickness was further studied using AFM. As gold nanofilm initial thickness increased, the thickness and diameter of AuNS increased simultaneously, which the increase was found to be more significant for AuNS formed on SiO₂/Si. The increase in dimension of AuNS would reduce the plasmonic performance due to increased travel distance cause more electron energy loss. Nevertheless, this result demonstrated the present approach not only could prepare hexagonal AuNS with reduced gold nanofilm thickness but also allowed preparation of AuNS with smaller dimension affecting the plasmonic performance.

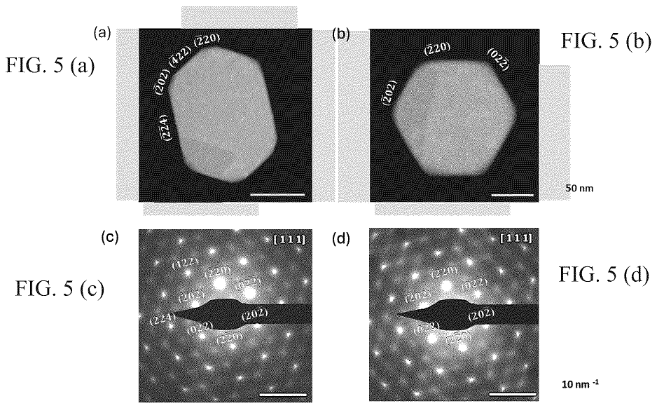

Apart from the morphological differences in gold nanostructures observed under SEM and AFM, transmission electron microscopy (TEM) was also used to examine the detailed crystal structures. As shown in FIG. 5(A)-FIG. 5(d), the HAADF-STEM images of sacrificed-MoS₂ AuNS with denoted surfaces (FIG. 5(a) and FIG. 5(b)) and corresponding selected area electron diffraction (SAED) images (FIG. 5(c) and FIG. 5(d)), implied that the Aus were single crystals, scale bars, 10 nm⁻¹. The selected region in HDDAF-STEM images labeled in red square was processed through fast Fourier Transformation (FFT) to obtain the FFT pattern (data not shown). For both the hexagonal-like and rod-like sacrificed-MoS₂ AuNS, the FFT pattern appeared in a hexagonal shape along the axis. By correlating the distance between reflection spots, it was affirmed that both gold nanostructures exhibited a face-centered cubic (FCC) structure, recognized as the thermodynamically stable form of gold, this result was also confirmed by selected area electron diffraction (SAED) (FIG. 5(c), FIG. 5(d)), the diffraction pattern demonstrated typical FCC structure along axis and proved both AuNS were single crystal.

By contrast, the FFT pattern of the nanostructure formed on SiO₂/Si also aligned with the FCC structure when reflected along the [1 1 2] axis. Further structural analysis on sacrificed-MoS₂ AuNS were revealed in HAADF-STEM images, different surfaces of the AuNS were selected to further observe the atomic structure. The high resolution STEM images exposed the presence of sharp edges with different type of atomic arrangement, including higher index surfaces and these images result agreed with the SAED pattern. Consequently, we had verified that the crystal structures of the gold nanostructures formed on both MoS₂ and SiO₂/Si are identical, conforming to the thermodynamically stable form and morphology difference, especially the sharp edges and corners presence in sacrificed-MoS₂ AuNS.

### 1.3 TMDCs/AuNS Photoluminescence (PL) Enhancement Performance

During the annealing process, the synthesized 2D TMDCs degraded, leaving only gold nanostructure on the substrate, which was confirmed by the missing of E¹_{2g} and A_{1g} peaks in Raman spectra (data not shown). To assess and compare the photoluminescence (PL) enhancement performance of MoS₂ and the gold nanostructures, MoS₂ was synthesized on a separate SiO₂/Si substrate and then stacked onto the AuNS using a dry transfer method to form the MoS₂/AuNS heterostructure, such as the process shown in FIG. 3. The monolayer MoS₂ flakes at the top covered various gold nanostructures. Part of the flakes covered sacrificed-MoS₂ AuNS distributed across a triangular shape, while the remaining area covered the AuNS formed on SiO₂/Si. Dark field optical microscopy provided improved observation of the gold nanostructure distribution and enhanced contrast between the two different AuNS.

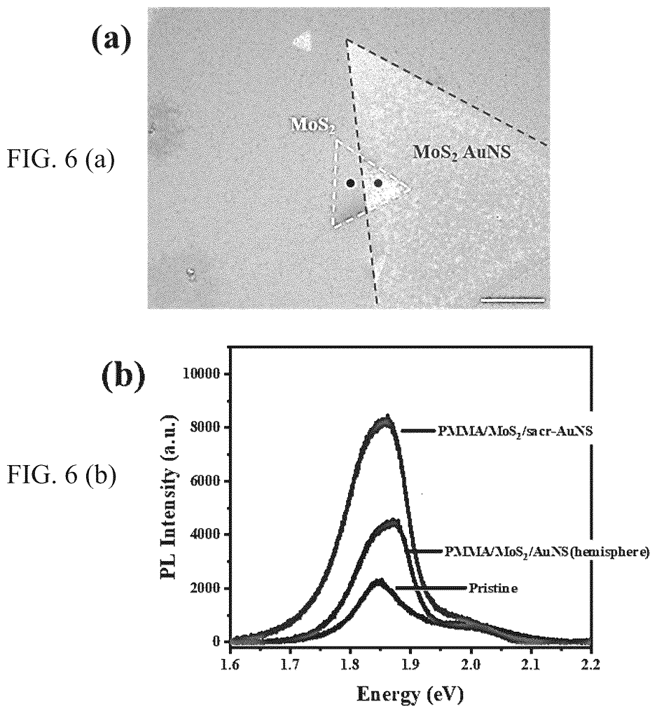

The stacked structure was then examined by Raman and photoluminescence spectroscopy. A line scan mapping was employed to measure Raman and PL signal under the excitation of 514 nm laser. The single point PL spectra of MoS₂ covering different AuNS was selected (FIG. 6(a)) and plotted in FIG. 6(b). It was found that the PL intensity of the main peak was significantly higher when MoS₂ covered sacrificial-MoS₂ AuNS compared to the hemisphere AuNS formed on SiO₂/Si, with an enhancement of approximately two times. Additionally, the pristine MoS₂ PL spectra before transfer was also plotted. Notably, after being transferred as part of the stacked structure, the PL intensity of MoS₂ was enhanced regardless of which AuNS was covered, compared to the pristine signal. This demonstrated that both types of AuNS could enhance the PL signal, albeit to different extents. Furthermore, it was observed that the main peak of the transferred MoS₂ was slightly blue-shifted in both regions compared to the pristine sample. Typically, the transfer of MoS₂ onto such nanostructures induced strain, which was expected to cause a red shift due to changes in the electronic structure. However, when the MoS₂ was transferred to large aggregate, the p-doping effect dominated the process, leading to a blue shift in the PL spectra, consistent with previous report.

To ensure the uniformity of transferred MoS₂ flake, Raman line mapping was analyzed in terms of peak distance and peak ratio, leveraging the unique layer-dependent Raman characteristics of MoS₂. The intrinsic properties of peak distance between E¹_{2g} and A_{1g} modes in MoS₂ allowed for the determination of the number of layers. The extracted peak distance was similar across the scan region, ranging from 19 to 20 cm⁻¹, indicating that the transferred MoS₂ was monolayer (data not shown). Moreover, intensity ratio between E¹_{2g} and A_{1g} was related to the crystallinity of MoS₂. A stable E¹_{2g}/A_{1g} ratio of approximately 0.55 to 0.65 (data not shown) across the scan region indicated no significant difference in crystallinity or defects within the examined MoS₂ flake. Thus, effects from crystallinity and sample quality was ruled out, and the PL enhancement was attributed to the gold nanostructures.

The enhancement of the PL signal was attributed to the plasmonic interaction between the incident light and the gold nanoparticles, which acted as localized plasmonic hot spots. As reported by Wen et al., similar heterostructure of Au/WS₂ has been studied. Under LSPR excitation conditions, additional electrons and excitons were generated by plasmon-induced charge transfer and field enhancement, explaining the PL enhancement in both hemisphere and sacr-AuNS. Owing to different excitation mechanisms, the enhancing ability could be determined by various factors, including the size and shape of AuNS.

Under normal circumstances, the smaller size of the nanoparticles would significantly influence this interaction, leading to a size-dependent resonance. Although larger particles were able to absorb and scatter more light increasing near-field intensities, the surface plasmons would tend to decay through photon emission other than exciting electron-hole pairs between AuNS and MoS₂, originated from the energy loss of electron travelling on metal surface to interface due to electron-electron scattering. Thus, we should expect higher enhancement of hemisphere AuNS but yet a lower enhancement was observed in the MoS₂ region integrated with hemisphere AuNS that prepared on SiO₂/Si surface.

As discussed in previous part relating to AuNS size, the present scar-AuNS was larger sized compared to hemisphere AuNS allowing higher absorption and scatter of light results in increased near-field intensities. Moreover, the electric field enhancement was maximized at sharp surfaces, making the corners of hexagonal or rod-like nanoparticles served as localized hotspots. These localized hotspots contained higher concentration of hot carriers and thus resulted in greater PL enhancement for gold nanostructures prepared on TMDCs compared to hemisphere gold nanostructures prepared on SiO₂/Si as resulted in the PL spectra in FIG. 6(b).

It will be understood that the above description of embodiments is given by way of example only and that various modifications may be made by those with ordinary skill in the art. The above specification, examples and data provide a complete description of the structure and use of exemplary embodiments of the invention. Although various embodiments of the invention have been described above with a certain degree of particularity, or with reference to one or more individual embodiments, those with ordinary skill in the art could make numerous alterations to the disclosed embodiments without departing from the spirit or scope of the present disclosure.

What is claimed is:

1. A method for producing a gold nanostructure on a sacrificed single-layer transition metal dichalcogenide (TMD) comprising:
(a) placing precursors of a first single-layer TMD and a first SiO₂/Si substrate in a chamber having a heating zone, wherein the precursors of the first single-layer TMD are disposed upstream to the heating zone while the first SiO₂/Si substrate is disposed in the heating zone;
(b) raising a temperature in the heating zone to 800-840° C. within 30 minutes in a presence of an inert gas and maintaining the temperature for 15 minutes to allow aligned growth of the first single-layer TMD on the first SiO₂/Si substrate;
(c) sputter-coating the product of step (b) with a film of gold; and
(d) annealing the product of step (c) at 600° C. for 20 minutes to degrade the first single-layer TMD thereby producing a gold nanostructure on the sacrificed single-layer TMD;
wherein,
the gold nanostructure on the sacrificed single-layer TMD exhibits an enhanced photoluminescence signal as compared to that of a gold nanostructure grown directly on the first SiO₂/Si substrate.

2. The method of claim 1, wherein
in step (a), the precursors of the first single-layer TMD are sulfur or selenium powders and MoO₃, and the first single-layer TMD is the first single-layer MoS₂ or MoSe₂; and
in step (b), the temperature in the heating zone is raised to 840° C.

3. The method of claim 1, wherein
In step (a), the precursors of the first single-layer TMD are sulfur or selenium powders and WO₃, and the first single-layer TMD is the first single-layer WS₂ or WSe₂;
in step (b), the temperature in the heating zone is raised to 820° C.

4. The method of claim 1, wherein in step (b), the inert gas is argon, helium or nitrogen.

5. The method of claim 1, wherein the gold nanostructure on the sacrificed single-layer TMD exhibits two times enhancement on the photoluminescence signal as compared to that of the gold nanostructure grown directly on the first SiO₂/Si substrate.

6. The method of claim 1, further comprising:
(e) stacking a second single-layer TMD onto the gold nanostructure on the sacrificed single-layer TMD of step (d) by a dry transfer method thereby forming a TMD/gold nanostructure stacked heterostructure;
wherein, the TMD/gold nanostructure stacked heterostructure exhibits four times enhancement on the photoluminescence signal as compared to that of the gold nanostructure grown directly on the first SiO₂/Si substrate.

7. The method of claim 6, wherein the second single-layer TMD is produced by,
(i) placing precursors of a second single-layer TMD and a second SiO₂/Si substrate in the chamber having the heating zone, wherein the precursors of the second single-layer TMD are disposed upstream to the heating zone while the second SiO₂/Si substrate is disposed in the heating zone; and
(ii) raising the temperature in the heating zone to 800-840° C. within 30 minutes in the presence of an inert gas and maintaining the temperature for 15 minutes to allow aligned growth of the second single-layer TMD on the second SiO₂/Si substrate.

8. The method of claim 7, wherein the dry transfer method of step (e) comprises steps of:
(1) spin-coating the second single-layer TMD of step (ii) with a transfer film;
(2) removing the second SiO₂/Si substrate from the product of step (1);
(3) placing the product of step (2) on top of the gold nanostructure on the sacrificed single-layer TMD of step (d) with the second single-layer TMD contacting the gold nanostructure on the sacrificed single-layer TMD of step (d);
(4) heating the product of step (3) at 120° C. for 2 minutes; and
(5) peeling off the transfer film from the heated product of step (4) thereby producing the TMD/gold nanostructure stacked heterostructure.

9. The method of claim 8, wherein the transfer film is polydimethylsiloxane (PDMS) or Poly(methyl methacrylate) (PMMA).

10. The method of claim 8, wherein the first or second single-layer TMD is selected from the group consisting of single-layer MoS₂, single-layer WS₂, single-layer MoSe₂, and single-layer WSe₂.
